(19) United States
(12) Patent Application Publication
(10) Pub. No.: US 2025/0194685 A1
(43) Pub. Date: Jun. 19, 2025

(54) A Method for Heat-Treating a Susceptor

(71) Applicant: JT International SA, Geneva (CH)

(72) Inventors: Branislav Zigmund, Vrbovce (SK); Stanislav Sliva, Ostrava (CZ); Daniel Vanko, Krpelany (SK)

(73) Assignee: JT International SA, Geneva (CH)

(21) Appl. No.: 18/847,989

(22) PCT Filed: Mar. 15, 2023
(86) PCT No.: PCT/EP2023/056580

§ 371 Date: Sep. 17, 2024

(30) Foreign Application Priority Data
Mar. 18, 2022 (EP) 22162904.1

(51) Int. Cl. A24F 40/465; A24F 40/70

(52) U.S. Cl. CPC A24F 40/465; A24F 40/70

(57) ABSTRACT

A method for heat-treating a susceptor includes heating a susceptor to a first temperature over a first time period, the first temperature being above 350° C. The method further includes holding the susceptor at the first temperature for a second time period and cooling the susceptor. A method of manufacturing an induction heating assembly for an aerosol generating system includes assembling the heat treated susceptor into an induction heating assembly.

### TECHNICAL FIELD

The present disclosure relates generally to a method for heat-treating a susceptor, and more particularly to a method for heat-treating a susceptor for an aerosol generating system.

### TECHNICAL BACKGROUND

Aerosol generating devices (also known as vaporisers) which heat, rather than burn or combust, an aerosol generating substrate to produce an aerosol for inhalation by a user of the device have become popular with consumers in recent years as an alternative to the use of traditional tobacco products.

Various devices and systems are available which can use one of a number of different approaches to provide heat to the aerosol generating substrate. One such approach is to provide an induction heating assembly. Such assemblies employ an electromagnetic field generator, such as an induction coil, to generate an alternating electromagnetic field that couples with, and inductively heats, a susceptor heating element. Heat from the susceptor is transferred, for example by conduction, to the substrate and an aerosol is generated as the substrate is heated for inhalation by a user of the device.

The temperature of an inductively heated susceptor can be estimated. Based on the estimated temperature, adjustments can be made to one or more operating parameters, such as moderating power supply to the induction coil, to maintain a target operating temperature to ensure a sufficient amount of vapour is generated during use.

The heating performance of an induction heating assembly is affected by a number of different properties of the susceptor, such as electrical resistance and inductance. Methods used to estimate the temperature of a susceptor during use may be based on the assumption that the properties of all substantially identical susceptors, i.e., susceptors made to the same geometry and made of the same material, are substantially the same or at least within a particular range.

However, in view of manufacturing tolerances there may be some variation in the properties of substantially identical susceptors. Furthermore, the properties of a susceptor may change during use, and potentially also between uses of the susceptor.

Temperature estimates may not therefore be accurate, i.e., may differ from the actual temperature of the susceptor, should one or more properties of a particular susceptor not be in accordance with assumptions made by the estimation method about the properties of that susceptor.

Any adjustment of operating parameters to maintain a target operating temperature of the susceptor may not therefore be optimum or even appropriate. This may cause an insufficient amount of vapour to be generated and a decrease in efficiency.

There is, therefore, a need to address this shortcoming.

### SUMMARY OF THE DISCLOSURE

According to a first aspect of the present disclosure, there is provided a method of manufacturing an induction heating assembly for an aerosol generating system, the method comprising:
heat treating a susceptor by:
   heating the susceptor to a first temperature over a first time period, the first temperature being above 350° C.;
   holding the susceptor at the first temperature for a second time period; and
   cooling the susceptor; and
assembling the heat treated susceptor into an induction heating assembly for an aerosol generating system.

The first temperature may be from 400° C. to 800° C., or may be from 600° C. to 700° C. The first temperature may be at least 400° C., or may be at least 450° C., or may be at least 500° C., or may be at least 600° C.

The first time period may be from 4 to 40 seconds, or preferably may be from 6 to 25 seconds, or most preferably may be from 10 to 20 seconds.

The second time period may be from 3 to 35 seconds, or preferably may be from 4 to 25 seconds, or most preferably may be from 5 to 15 seconds.

Possibly, the method comprises:
cooling the susceptor from the first temperature to a second temperature over a third time period.

The second temperature may be from 20° C. to 150° C. lower than the first temperature, or preferably may be from 30° C. to 100° C. lower than the first temperature, or most preferably may be from 40° C. to 60° C. lower than the first temperature.

The third time period may be from 5 to 45 seconds, or preferably may be from 10 to 35 seconds, or most preferably may be from 15 to 25 seconds.

Possibly, the method comprises:
cooling the susceptor from the second temperature to ambient temperature over a fourth time period, wherein the fourth time period is the time required for the susceptor to cool to ambient temperature.

At least the step of heating the susceptor to the first temperature may be carried out at ambient atmospheric pressure. Alternatively, at least the step of heating the susceptor to the first temperature may be carried out at a pressure above ambient atmospheric pressure. Alternatively, at least the step of heating the susceptor to the first temperature may be carried out at a pressure below ambient atmospheric pressure.

At least the step of heating the susceptor to the first temperature may be carried out under a normal atmospheric composition. Alternatively, at least the step of heating the susceptor to the first temperature may be carried out under a composition which differs from a normal atmospheric composition. The composition may comprise an inert gas. Alternatively, the composition may comprise an active gas.

The steps of heat treating the susceptor may be carried out in an oven or kiln.

The susceptor may be substantially cylindrical. The susceptor may be as susceptor tube. Alternatively, the susceptor may be substantially planar. The susceptor may be a susceptor strip.

The susceptor may comprise a heating element of the aerosol generating system, wherein the aerosol generating system comprises an aerosol generating device and an aerosol generating substrate. The method may further comprise heating the susceptor in the aerosol generating system to a target temperature operable to generate a vapour from the aerosol generating substrate: estimating a temperature of the susceptor during said heating; and adjusting one or more operating parameters of the aerosol generating device using the estimated temperature in order to maintain the target temperature.

According to a second aspect of the present disclosure, there is provided an induction heating assembly for an aerosol generating system, the induction heating assembly produced according to the method of any of the above paragraphs.

According to a further aspect of the present disclosure, there is provided a method for heat-treating a susceptor, the method comprising:
heating a susceptor to a first temperature over a first time period, the first temperature being above 350° C.;
holding the susceptor at the first temperature for a second time period; and
cooling the susceptor.

According to another aspect of the present disclosure, there is provided a heat-treated susceptor provided by the method of any of the above paragraphs.

It has been surprisingly found that the properties, such as electrical resistance and inductance, of all substantially identical susceptors having been subject to the described heat-treatment method, i.e., heat-treated susceptors, are substantially the same or at least within a particular range. Any variations in the properties caused by manufacturing tolerances have therefore been mitigated by the described heat-treatment method. Furthermore, the properties of such heat-treated susceptors do not significantly change during use, or between uses of the susceptors.

Accordingly, in use, there is correspondence, i.e., a very close similarity, between the estimated temperature and the actual temperature of all substantially identical heat-treated susceptors. Temperature estimates in relation to heat-treated susceptors remain accurate, i.e., correspond to the actual susceptor temperature, during use and between uses of the susceptor. Any adjustment of operating parameters to maintain a target operating temperature of a heat-treated susceptor based on such temperature estimates will therefore be optimum and appropriate. This ensures a sufficient amount of vapour will be generated during use and a improves efficiency.

### BRIEF DESCRIPTION OF THE DRAWINGS

FIG. 1 is a diagrammatic view of an aerosol generating system:

FIG. 2 is a diagrammatic perspective view of a susceptor:

FIG. 3 is a diagrammatic perspective view of another susceptor:

FIG. 4 illustrates a method for heat-treating a susceptor:

FIG. 5 is a graphical representation of a heat-treatment profile:

FIG. 6a is a graphical representation of the inductance of a number of substantially identical susceptors before heat-treatment:

FIG. 6b is a graphical representation of the inductance of the susceptors after heat-treatment:

FIG. 7a is a graphical representation of the electrical resistance of a number of substantially identical susceptors before heat-treatment:

FIG. 7b is a graphical representation of the electrical resistance of the susceptors after heat-treatment:

FIG. 8a is a graphical representation showing a comparison between estimated susceptor temperature and measured susceptor temperature before heat-treatment:

FIG. 8b is a graphical representation showing a comparison between estimated susceptor temperature and measured susceptor temperature after heat-treatment:

FIG. 9a is a graphical representation showing a comparison of transfer function of a number of substantially identical susceptors before heat-treatment; and

FIG. 9b is a graphical representation showing a comparison of transfer function of the susceptors after heat-treatment.

### DETAILED DESCRIPTION OF EMBODIMENTS

Embodiments of the present disclosure will now be described by way of example only and with reference to the accompanying drawings.

Examples of the disclosure provide a method for heat-treating a susceptor 10. Examples of the disclosure also provide a heat-treated susceptor 10 being the product of the described method.

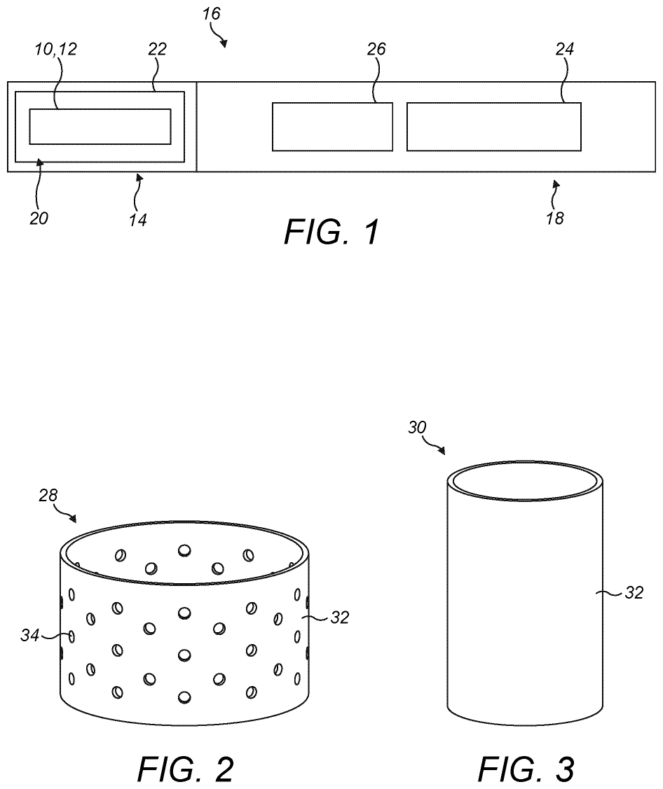

As shown diagrammatically in FIG. 1, a susceptor 10 according to examples of the disclosure is useable as a heating element 12 as part of an induction heating assembly 14, i.e., an induction heating system, of an aerosol generating system 16. An aerosol generating system 16 comprises an aerosol generating device 18 (also known as a vaporiser) and an aerosol generating substrate 20. An aerosol generating device 18 is a hand-held, portable, device, by which it is meant that a user is able to hold and support the device 18 unaided, in a single hand.

In use, an induction coil 22, i.e., an electromagnetic field generator, comprised in the induction heating assembly 14 is arranged to be energised to generate an alternating electromagnetic field that couples with, and inductively heats, the susceptor 10 due to eddy currents and magnetic hysteresis losses resulting in a conversion of energy from electromagnetic to heat. Heat from the susceptor 10 is transferred, for example by conduction, radiation and convection, to the aerosol generating substrate 20 to heat the aerosol generating substrate 20 (without burning or combusting the aerosol generating substrate 20) thereby generating a vapour which cools and condenses to form an aerosol for inhalation by a user of the aerosol generating device 18.

In general terms, a vapour is a substance in the gas phase at a temperature lower than its critical temperature, which means that the vapour can be condensed to a liquid by increasing its pressure without reducing the temperature, whereas an aerosol is a suspension of fine solid particles or liquid droplets, in air or another gas. It should, however, be noted that the terms ‘aerosol’ and ‘vapour’ may be used interchangeably in this specification, particularly with regard to the form of the inhalable medium that is generated for inhalation by a user.

The induction coil 22 is energised by a power source 24 of the aerosol generating device 18, such as a battery. Aerosol generating devices 10 typically include a controller 26 and a user interface for controlling the operation of the aerosol generating device 18 via the controller 26.

The controller 26 is configured to detect the initiation of use of the aerosol generating device 18, for example, in response to a user input, such as a button press to activate the aerosol generating device 18, or in response to a detected airflow through the aerosol generating device 18. As will be understood by one of ordinary skill in the art, an airflow through the aerosol generating device 18 is indicative of a user inhalation or ‘puff’. The aerosol generating device 18 may, for example, include a puff detector, such as an airflow sensor (not shown), to detect an airflow through the aerosol generating device 18.

The controller 26 includes electronic circuitry. The power source 24 and the electronic circuitry may be configured to operate at a high frequency. For example, the power source 24 and the electronic circuitry may be configured to operate at a frequency of between approximately 80 KHz and 500 kHz, possibly between approximately 150 kHz and 250 kHz, and possibly at approximately 200 kHz. The power source 24 and the electronic circuitry could be configured to operate at a higher frequency, for example in the MHz range, if required.

The induction coil 22 may be arranged around the susceptor 10, for example to surround or fully surround the susceptor 10. The induction coil 22 may be substantially helical in shape. The induction coil 22 may be annular. The induction coil 22 may comprise a Litz wire or a Litz cable. It will, however, be understood that other materials could be used. The induction coil 22 may be arranged to operate in use with a fluctuating electromagnetic field having a magnetic flux density of between approximately 20 mT and approximately 2.0T at the point of highest concentration.

The induction heating assembly 14 may have an arrangement in which one or more susceptors 10 are arranged around the periphery of a heating compartment (not shown) configured for receiving an aerosol generating substrate 20. Alternatively, in other arrangements a susceptor 10 may be arranged to project into a heating compartment (not shown) from an end of the heating compartment to penetrate the aerosol generating substrate 20 when the aerosol generating substrate 20 is received in the heating compartment. In such examples, the susceptor 10 may be a blade or pin as described below. In these examples, the susceptor 20 is comprised in the aerosol generating device 18, as illustrated diagrammatically in FIG. 1.

In other arrangements, the susceptor 10 is instead provided in the aerosol generating substrate 20 during manufacture.

In examples of the disclosure, the susceptor 10 comprises an electrically conductive material. The susceptor 10 may comprise one or more, but not limited to, of graphite, molybdenum, silicon carbide, niobium, aluminium, iron, nickel, nickel containing compounds, titanium, mild steel, stainless steel, low carbon steel and alloys thereof, e.g., nickel chromium or nickel copper, and composites of metallic materials. In some examples, the susceptor 10 comprises a metal selected from the group consisting of mild steel, stainless steel, and low carbon stainless steel.

Susceptors 10 according to examples of the disclosure may comprise a variety of geometrical configurations. For instance, a susceptor 10 may be cylindrical (i.e., a cylindrical susceptor or substantially cylindrical susceptor), or planar (i.e., a planar susceptor or substantially planar susceptor). Susceptors 10 may be open-ended, hollow and/or elongate. Specific examples of susceptors 10 according to examples of the disclosure include, but are not limited to, a particulate susceptor, a susceptor filament, a susceptor mesh, a susceptor wick, a susceptor pin, a susceptor rod, a susceptor blade, a susceptor strip, a susceptor sleeve, a susceptor tube, a susceptor ring, and a susceptor cup. A susceptor strip may be elongate.

FIGS. 2 and 3, respectively show examples of different types of susceptor tubes 28, 30 each having a tube wall 32.

Regarding the susceptor tube 28 shown in FIG. 2, openings 34 extend through the tube wall 32. The openings 34 are apertures, through-holes, or perforations. Accordingly, the tube wall 32 comprises a plurality of openings 34. The openings 34 are substantially circular shaped openings. In other examples, the openings 34 may have a different shape. The openings 34 are distributed over the majority of the tube wall 32. The openings 34 are arranged in rows. Each row extends around the circumference of the susceptor tube 28. Accordingly, the openings 34 are arranged in circumferentially adjacent rows. The openings 34 in adjacent rows are staggered. Accordingly, the openings 34 in each row are axially offset from the openings 34 in circumferentially adjacent rows to provide a staggered arrangement of the openings 34. The openings 34 in each row are uniformly spaced apart. The rows are uniformly spaced apart.

The susceptor tube 28 may be an outer susceptor or peripheral susceptor, i.e., locatable on the outside of an aerosol generating substrate.

Referring to FIG. 3, the susceptor tube 30 has a longer axial length and a reduced diameter compared to the susceptor tube 28 shown in FIG. 2. Furthermore, the tube wall 32 of the susceptor tube 30 does not comprise openings extending therethrough. The susceptor tube 30 may be a central or inner susceptor, i.e., locatable within an aerosol generating substrate or on the inside of an aerosol generating substrate.

Susceptors 10 according to examples of the disclosure may have a thickness up to 150 μm, or up to 300 μm, or preferably may have a thickness from 30 μm to 300 μm, or more preferably may have a thickness from 100 μm to 150 μm, or most preferably may have a thickness of 100 μm. A susceptor 10 having these thickness dimensions may be particularly suitable for being inductively heated during use.

During use of an aerosol generating system 16, the temperature of an inductively heated susceptor 10, i.e., a susceptor 10 which has been inductively heated or is being inductively heated, can be estimated, for instance by the controller 26, using one of a number of different methods. Such methods may rely on an algorithm.

In some examples, the temperature estimation may be based on the electrical resistance of the susceptor 10. Electrical resistance changes proportionally with susceptor 10 temperature. During induction heating, the change in the electrical resistance of the susceptor 10 can be observed as a change in resonance frequency and/or a change in the amplitude of resonance peak voltage. Preferably, in such examples an estimation of susceptor 10 temperature is based on resonance peak voltage because this is generally more sensitive to a change in electrical resistance of the susceptor 10.

Based on the estimated temperature, adjustments can be made to one or more operating parameters, such as moderating power supply from the power source 24 to the induction coil 22, to maintain a target operating temperature to ensure a sufficient amount of vapour is generated during use. The normal operational temperature of a susceptor 10 in an induction heating assembly 14 of an aerosol generating system 16 is about 350° C., or up to 350° C.

The heating performance of an induction heating assembly 14 is affected by a number of different properties of the susceptor 10, such as electrical resistance and inductance. Methods used to estimate the temperature of a susceptor 10 during use may be based on the assumption that the properties of all substantially identical susceptors 10, i.e., susceptors 10 made to the same geometry and made of the same material, are substantially the same or at least within a particular range.

However, in view of manufacturing tolerances there may be some variation in the properties of substantially identical susceptors 10. Furthermore, the properties of a susceptor 10 may change during use, and potentially also between uses of the susceptor 10.

Temperature estimates may not therefore be accurate, i.e., may differ from the actual temperature of the susceptor 10, should one or more properties of a particular susceptor 10 not be in accordance with assumptions made by the estimation method about the properties of that susceptor 10.

Any adjustment of operating parameters to maintain a target operating temperature of the susceptor 10 may not therefore be optimum or even appropriate. This may cause an insufficient amount of vapour to be generated and a decrease in efficiency.

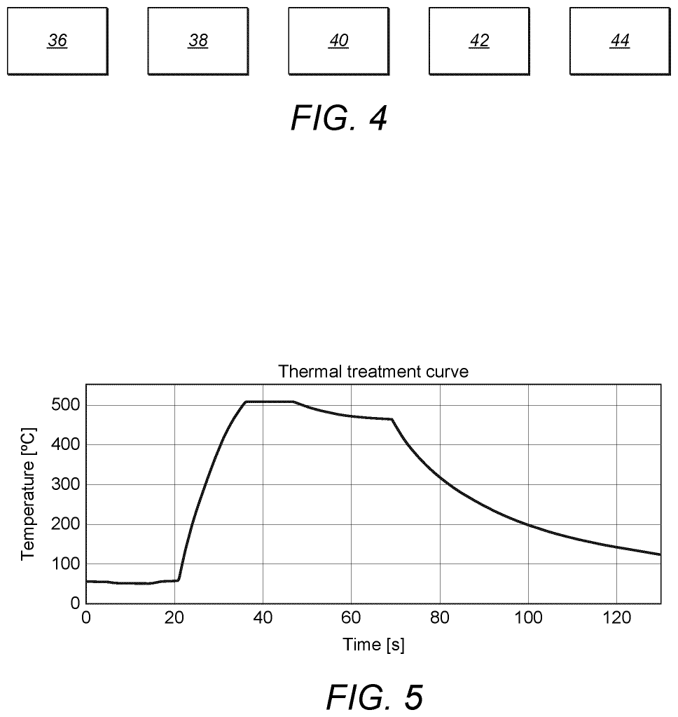

FIG. 4 illustrates a method for heat-treating a susceptor 10. As evidenced below, it has been surprisingly found that the properties, such as electrical resistance and inductance, of all substantially identical susceptors 10 having been subject to the described heat-treatment method, i.e., heat-treated susceptors 10, are substantially the same or at least within a particular range. Any variations in the properties caused by manufacturing tolerances have therefore been mitigated by the described heat-treatment method. Furthermore, the properties of such heat-treated susceptors 10 do not significantly change during use, or between uses of the susceptors 10.

Accordingly, in use, there is correspondence, i.e., a very close similarity, between estimated temperature and actual temperature of all substantially identical heat-treated susceptors 10. Temperature estimates in relation to heat-treated susceptors 10 remain accurate, i.e., correspond to the actual susceptor temperature, during use and between uses of the susceptor 10. Any adjustment of operating parameters to maintain a target operating temperature of a heat-treated susceptor 10 based on such temperature estimates will therefore be optimum and appropriate. This ensures a sufficient amount of vapour will be generated during use and a improves efficiency.

Referring to FIG. 4, and with reference to block 36, the method comprises heating a susceptor 10 to a first temperature over a first time period.

In some examples, at least the step of heating the susceptor 10 to the first temperature is carried out at ambient atmospheric pressure. The disclosure therefore covers examples in which a part of the heat-treating process is carried out at ambient atmospheric pressure and examples in which the entire heat-treating process is carried out at ambient atmospheric pressure.

In other examples, at least the step of heating the susceptor 10 to the first temperature is carried out at a pressure above ambient atmospheric pressure. Alternatively, at least the step of heating the susceptor 10 to the first temperature may be carried out at a pressure below ambient atmospheric pressure.

The disclosure therefore covers examples in which a part of the heat-treating process is carried out at a pressure above or below ambient atmospheric pressure and examples in which the entire heat-treating process is carried out at a pressure above or below ambient atmospheric pressure.

At least the step of heating the susceptor 10 to the first temperature may be carried out under a normal atmospheric composition. The disclosure therefore covers examples in which a part of the heat-treating process is carried out under a normal atmospheric composition and examples in which the entire heat-treating process is carried out under a normal atmospheric composition.

Alternatively, at least the step of heating the susceptor 10 to the first temperature may be carried out under a composition which differs from a normal atmospheric composition, i.e., under a shielding gas. In such examples, the composition may comprise an inert gas (or inert gases). Alternatively, the composition may comprise an active gas (or active gases). The composition may consist of an inert gas(es) or active gas(es). The major component of the composition may be an inert gas(es) or active gas(es). The disclosure therefore covers examples in which a part of the heat-treating process is carried out under a composition which differs from the normal atmospheric composition and examples in which the entire heat-treating process is carried out under a composition which differs from the normal atmospheric composition.

An inert gas is chemically inert and remains stable at the first temperature. Accordingly, inert gases do not alter any characteristics of the susceptor 10. Inert gases include nitrogen, argon, and helium, for example.

An active gas is chemically active at the first temperature. At the first temperature active gases may break down or become unstable and subsequently induce a chemical reaction(s) with the material of the susceptor 10 to alter one or more characteristics of the susceptor 10, for example, to change the chemical and/or mechanical properties of the susceptor.

The first temperature is above 350° C., which as described above is the normal operational temperature of a susceptor 10 in an induction heating assembly 14 of an aerosol generating system 16. The first temperature may be from 400° C. to 800° C. The first temperature may be from 600° C. to 700° C. In some examples, the first temperature is at least 400° C. In other examples, the first temperature is at least 450° C., or at least 500° C., or at least 600° C. The first temperature may be above 700° C.

The first time period may be from 4 to 40 seconds. Preferably, the first time period is from 6 to 25 seconds. Most preferably, the first time period is from 10 to 20 seconds.

With reference to block 38, the method further comprises holding the susceptor at the first temperature for a second time period. The second time period may be from 3 to 35 seconds. Preferably, the second time period is from 4 to 25 seconds. Most preferably, the second time period is from 5 to 15 seconds.

With reference to block 40, the method comprises cooling the susceptor 10. Referring to block 42, in some examples, the method comprises cooling the susceptor 10 from the first temperature to a second temperature over a third time period.

The second temperature may be from 20° C. to 150° C. lower than the first temperature. Preferably, the second temperature is from 30° C. to 100° C. lower than the first temperature. Most preferably, the second temperature is from 40° C. to 60° C. lower than the first temperature.

The third time period may be from 5 to 45 seconds. Preferably, the third time period is from 10 to 35 seconds. Most preferably, the third time period is from 15 to 25 seconds. Cooling the susceptor from the first temperature to the second temperature over the third time period represents a period of controlled cooling.

Referring to block 44, in some examples the method comprises cooling the susceptor 10 from the second temperature to ambient temperature over a fourth time period. The fourth time period is the time required for the susceptor 10 to cool to ambient temperature following discontinuation of heating.

In some examples, the susceptor 10 is heated using an induction coil 22, for instance of the type described above. The susceptor 10 and/or induction coil 22 may be disposed in a heating chamber, for example an oven, during the heat-treatment method. In such examples, the induction coil 22 is arranged around the susceptor 10, for example to surround or fully surround the susceptor 10.

In other examples, the susceptor 10 is flame-heated using a gas torch, for example, in a heating chamber, oven or kiln. In such examples, the first temperature is above 700° C. A colour change in the heat-treated susceptor 10 may be observed.

FIG. 5 shows a graphical representation of a heat-treatment profile, i.e., a thermal curve, for an example heat-treatment method. Referring to FIG. 5, and reading the graph from left to right, following commencement of heating using an induction coil arranged around a susceptor 10 a sharp increase in the measured temperature of the susceptor 10 is observed from a start temperature of about 50° C. to a first temperature of about 500° C. over a first time period of about 15 seconds.

The susceptor 10 is held at the first temperature of about 500° C. for a second time period of about 10 seconds.

Controlled cooling of the susceptor 10 to a second temperature of about 450° C. follows over a third time period of about 20 seconds. The susceptor 10 is then allowed to cool to ambient temperature gradually without control. In the illustrated example, and following discontinuation of heating, the temperature of the susceptor 10 decreases from the second temperature of about 450° C. to about 60° C. over a time period of about 60 seconds. The period of time required for the susceptor 10 to cool from the second temperature to ambient temperature is a fourth time period. The full extent of the fourth time period is not show in the graph of FIG. 5.

In some examples, the start temperature of the susceptor 10 is ambient temperature. In other examples, the start temperature of the susceptor 10 may be above ambient temperature (as is the case above in relation to FIG. 5), for instance, if the susceptor 10 has been pre-heated prior to commencement of the heat-treatment method.

In some examples, it is desirable to provide a heat-treatment profile wherein the susceptor 10 is heated to a minimum possible first temperature and over the shortest possible time period to reduce energy consumption. This is particularly the case for mass-scale manufacturing.

The heat-treatment profile graphically represented in FIG. 5 has been found to be highly repeatable.

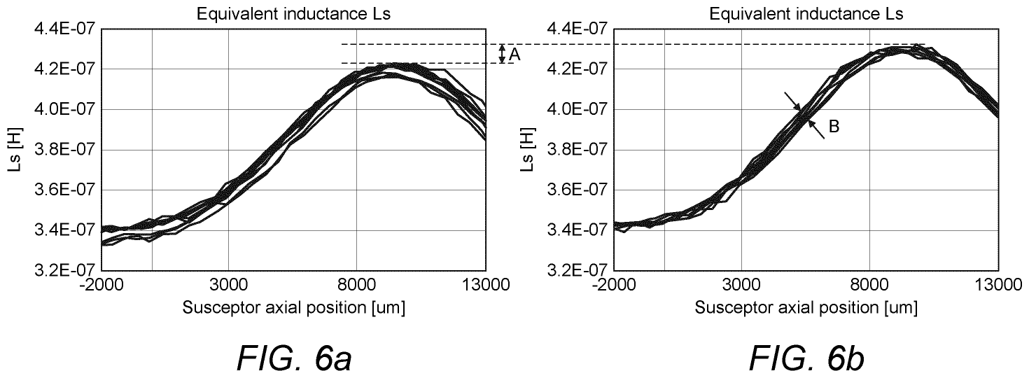

The graphs of FIGS. 6a and 6b respectively show the inductance (Ls) of a number of substantially identical susceptors 10 located at different axial positions (measured in μm) in an induction heating assembly before and after heat-treatment as described above.

It is apparent from a consideration of FIGS. 6a and 6b that the heat-treated susceptors 10 have a higher inductance of about 16 nH, as indicated by label (A). Furthermore, there is less variation in inductance between the heat-treated susceptors 10, as indicated by label (B).

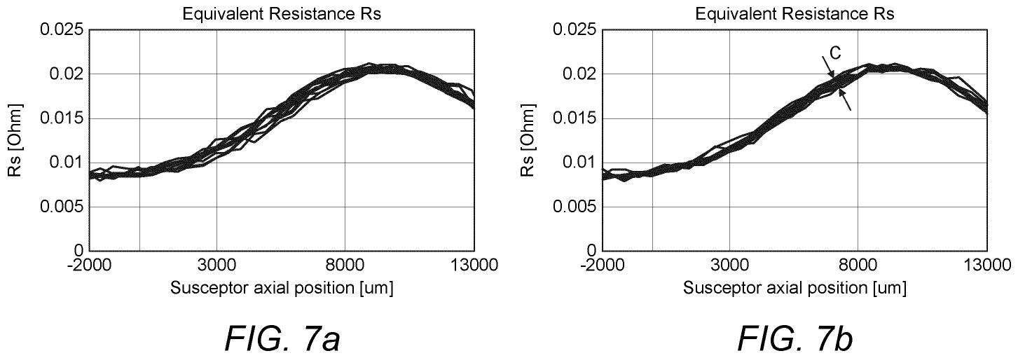

The graphs of FIGS. 7a and 7b respectively show the electrical resistance (Rs) of a number of substantially identical susceptors 10 located at different axial positions (measured in μm) in an induction heating assembly before and after heat-treatment as described above.

It is apparent from a consideration of FIGS. 7a and 7b that there is less variation in electrical resistance between the heated-treated susceptors 10, as indicated by label (C).

Electrical properties (i.e., electrical resistance and inductance) of heat-treated susceptors 10, i.e., for an electrical circuit, are thus stabilised. The heat-treatment method therefore changes electrical properties of the susceptor 10, or at least a surface layer of the susceptor 10.

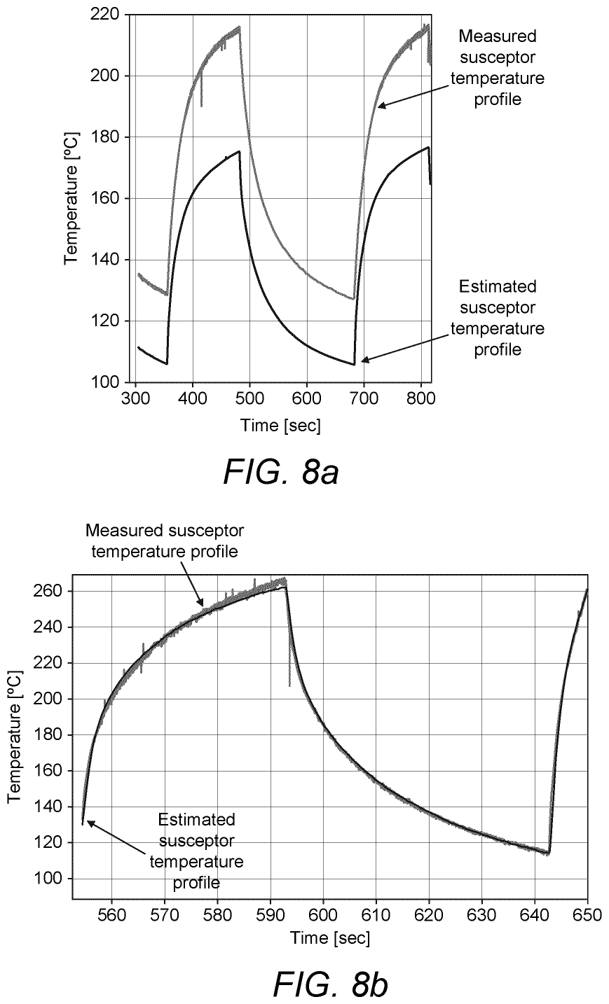

The graphs of FIGS. 8a and 8b respectively compare the measured temperature of an inductively heated susceptor 10 (i.e., the actual susceptor temperature) with an estimation of the susceptor temperature over a time period before and after heat-treatment as described above.

The susceptor 10 was inductively heated using an induction coil arranged to fully surround the susceptor 10. The induction coil 22 is of the type described above and had seven turns, an inductance of 0.340 μH and a resistance of 9.7 mOhm. The susceptor 10 had an outer diameter of 5 mm, a wall thickens of 150 μm and an axial length of 7 mm.

The temperature of the susceptor 10 was varied over the time period indicated in the graph. The power supply to the induction coil was moderated to vary the temperature of the susceptor 10 over the time period.

A non-contact method was used to measure the actual temperature of the susceptor 10. In particular, the thermal radiation emitted from the susceptor 10 over the time period was reflected using a mirror having a reflective surface comprising gold. The reflection of the thermal radiation was detected using a thermal imaging camera to provide a measured susceptor temperature profile over the time period. In the graphs of FIGS. 8a and 8b, the measured susceptor temperature profile (corresponding to the actual susceptor 10 temperature) is compared with an estimated susceptor temperature profile over the same time period.

It is apparent from a consideration of FIGS. 8a and 8b that there is considerably better correspondence, i.e., a much closer similarity, between the estimated temperature and the actual measured temperature of the heat-treated susceptor 10.

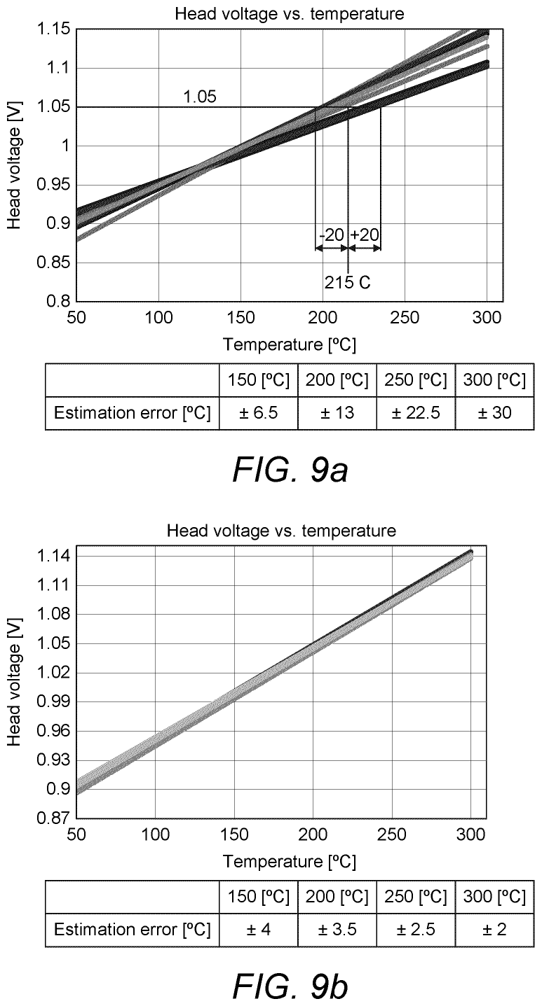

The graphs of FIGS. 9a and 9b respectively show a comparison of transfer function of a number of substantially identical susceptors 10 before and after heat-treatment as described above. Typically, manufacturing tolerances produce variations in transfer function, leading to temperature estimation errors as illustrated in FIG. 9a, i.e., slope variations are observed. It is apparent from a consideration of FIGS. 9a and 9b that temperature estimation errors are smaller for heat-treated susceptors 10. The temperature estimation error at 300° C. is in fact over 10 times smaller for heat-treated susceptors 10 (i.e., ±30° C. without heat-treatment compared to ±2° C. for heat-treated susceptors 10).

It has also surprisingly been found that heat-treated susceptors 10 are more responsive to an electromagnetic field induced by an induction coil 22. Accordingly, heat-treated susceptors 10 heat up more rapidly and provide more efficient inductive heating.

Without being bound by theory, the improvements observed may be the result of the heat-treatment method causing a mechanical, metallurgical, or chemical change to the susceptor 10, which may be confined to a surface layer of the susceptor 10 (skin depth), causing a change in properties such as electrical resistance and/or inductance.

A mechanical change may relieve mechanical stress created by manufacture of the susceptor 10. A metallurgical change may be defined by a change in grain structure or crystal structure. A chemical change may involve carbon atoms being fused to the surface of the susceptor 10 or the susceptor's 10 metal surface is reacts with gasses which are contained in air (For example NOx, CO₂).

Examples of the disclosure also provide a heat-treated susceptor 10 and an induction heating assembly 14 comprising a heat treated susceptor 10.

The Figures also illustrate a method of manufacturing an aerosol generating device 18 comprising an induction heating assembly 14, wherein the induction heating assembly 14 comprises a heat-treated susceptor 10. The Figures also illustrate a method of providing an aerosol generating system 16 according to examples of the disclosure.

Although exemplary embodiments have been described in the preceding paragraphs, it should be understood that various modifications may be made to those embodiments without departing from the scope of the appended claims. Thus, the breadth and scope of the claims should not be limited to the above-described exemplary embodiments.

Any combination of the above-described features in all possible variations thereof is encompassed by the present disclosure unless otherwise indicated herein or otherwise clearly contradicted by context.

Unless the context clearly requires otherwise, throughout the description and the claims, the words “comprise”, “comprising”, and the like, are to be construed in an inclusive as opposed to an exclusive or exhaustive sense: that is to say, in the sense of “including, but not limited to”

1. A method of manufacturing an induction heating assembly for an aerosol generating system, the method comprising:
heat treating a susceptor by:
heating the susceptor to a first temperature over a first time period, the first temperature being above 350° C.;
holding the susceptor at the first temperature for a second time period; and
cooling the susceptor; and
assembling the heat treated susceptor into an induction heating assembly for an aerosol generating system.

2. The method according to claim 1, wherein the first temperature is at least 400° C.

3. The method according to claim 1, wherein the first temperature is at least 500° C.

4. The method according to claim 1, wherein the first time period is from 4 to 40 seconds.

5. The method according to claim 1, wherein the second time period is from 3 to 35 seconds.

6. The method according to claim 1, further comprising:
cooling the susceptor from the first temperature to a second temperature over a third time period.

7. The method according to claim 6, wherein the second temperature is from 20° C. to 150° C. lower than the first temperature.

8. The method according to claim 6, wherein the third time period is from 5 to 45 seconds.

9. The method according to claim 6, wherein the method comprises further comprising:
cooling the susceptor from the second temperature to ambient temperature over a fourth time period, wherein the fourth time period is the time required for the susceptor to cool to ambient temperature.

10. The method according to claim 1, wherein at least the step of heating the susceptor to the first temperature is carried out at ambient atmospheric pressure.

11. The method according to claim 1, wherein at least the step of heating the susceptor to the first temperature is carried out at a pressure above or below ambient atmospheric pressure.

12. The method according to claim 1, wherein the steps of heat treating the susceptor are carried out in an oven or a kiln.

13. The method according to claim 1, wherein at least the step of heating the susceptor to the first temperature is carried out under a normal atmospheric composition.

14. The method according to claim 1, wherein at least the step of heating the susceptor to the first temperature is carried out under a composition which differs from a normal atmospheric composition.

15. The method according to claim 14, wherein the composition comprises one of an inert gas and an active gas.
